(19) United States
(12) Patent Application Publication
(10) Pub. No.: US 2026/0059721 A1
(43) Pub. Date: Feb. 26, 2026

(54) POWER CONVERSION SYSTEM AND ENERGY STORAGE SYSTEM

(71) Applicant: ZHEJIANG JINKO ENERGY STORAGE CO., LTD., Haining City (CN)

(72) Inventor: Luhua ZHANG, Haining City (CN)

(21) Appl. No.: 18/928,615

(22) Filed: Oct. 28, 2024

(30) Foreign Application Priority Data
Aug. 26, 2024 (CN) 202411178560.6

(51) Int. Cl. H05K 7/20; H02M 7/00; H05K 7/14

(52) U.S. Cl. CPC H05K 7/20909; H05K 7/1432; H05K 7/20927; H02M 7/003

(57) ABSTRACT

An power conversion system includes: a tank comprising a body and a partition wall arranged in the body, the partition wall dividing an interior of the body into a first cavity and a second cavity, the partition wall being provided with a plurality of vents, the plurality of vents being communicated between the first cavity and the second cavity; a liquid cooling member located in the second cavity and at least attached to the partition wall; and an airflow generator arranged in the first cavity, the airflow generator being configured to input gas located in the second cavity into the first cavity via at least one vent and output gas located in the first cavity into the second cavity via at least another vent.

### CROSS-REFERENCE TO RELATED APPLICATIONS

This application claims priority of Chinese Patent Application No. 2024111785606, filed on Aug. 26, 2024, entitled “POWER CONVERSION SYSTEM AND ENERGY STORAGE SYSTEM”, the entire content of which is incorporated herein by reference in its entirety.

### TECHNICAL FIELD

The present disclosure relates to the field of energy storage technologies, and in particular to a power conversion system and an energy storage system having the same.

### BACKGROUND

As a small power electronic device, power conversion system is a core device of an energy storage system. With rapid development of energy storage technologies, the power conversion systems with same power are becoming smaller in size, which puts forward higher requirements for heat dissipation effects of power conversion systems.

### SUMMARY

Accordingly, it is necessary to provide a power conversion system and an energy storage system to improve the heat dissipation effect when space is limited.

According to one aspect, a power conversion system is provided, including: a tank including a body and a partition wall arranged in the body; the partition wall dividing an interior of the body into a first cavity and a second cavity, the partition wall being provided with a plurality of vents, the plurality of vents being communicated between the first cavity and the second cavity; a liquid cooling member located in the second cavity and at least attached to the partition wall; and an airflow generator arranged in the first cavity; the airflow generator being configured to input gas located in the second cavity into the first cavity via at least one vent and output gas located in the first cavity into the second cavity via at least another vent.

In an embodiment, the partition wall has two first sides oppositely arranged along a first direction, the first direction intersecting with a direction in which the first cavity points to the second cavity; all the vents are arranged adjacent to the two first sides respectively, and all the vents are configured to cooperate with the airflow generator to form an annular airflow that circulates from the first cavity to the second cavity.

In an embodiment, in all the vents, the vents for air inlet are defined as first vents, and the vents for air outlet are defined as second vents; and the airflow generator includes at least one first airflow generating unit, and inlets of the first airflow generating unit and the first vents are communicated in one-to-one correspondence.

In an embodiment, a plurality of first vents and a plurality of first airflow generating units are provided; and all the first vents are arranged adjacent to one of the first sides, and the second vents are arranged adjacent to the other of the first sides.

In an embodiment, one second vent is provided; and orthographic projections of all the first vents on a reference plane are located within a range of an orthographic projection of the second vent on the reference plane; the reference plane is a plane perpendicular to a direction in which the first side points to the second side; and/or all the first vents are sequentially spaced apart along a preset direction; and the preset direction, the first direction, and the direction in which the first cavity points to the second cavity are perpendicular to each other; and/or outlets of the first airflow generating units are arranged towards the second vents, and the outlets of the first airflow generating units are oriented parallel to the first direction; and/or two first vents and two first airflow generating units are provided, and one of the first vents is arranged adjacent to one end of one of the first sides, and the other of the first vents is arranged adjacent to the other end of the one of the first sides.

In an embodiment, the partition wall further has two second sides oppositely arranged along a second direction; each of the first sides connects the two second sides, and each of the first sides and the two second sides define two corner portions; the first direction, the second direction, and the direction in which the first cavity points to the second cavity are perpendicular to each other; and a plurality of first vents, a plurality of second vents, and a plurality of first airflow generating units are provided; and at least one of the first airflow generating units is arranged at a first target corner portion, and the rest of the first airflow generating units are located at a second target corner portion; the first target corner portion and the second target corner portion are two corner portions in all the corner portions and not adjacent along a circumferential direction of the partition wall; at least one of the second vents is located on an air outlet path of at least one of the first airflow generating units, and the rest of the second vents are located on air outlet paths of the rest of the first airflow generating units.

In an embodiment, in the four corner portions, the corner portions other than the first target corner portion and the second target corner portion are a third target corner portion and a fourth target corner portion; an outlet of at least one of the first airflow generating units is arranged towards the third target corner portion, and at least one of the second vents is arranged at the third target corner portion; and outlets of the rest of the first airflow generating units are arranged toward the fourth target corner portion, and the rest of the second vents are arranged at the fourth target corner portion; and/or two first vents, two second vents, and two first airflow generating units are provided.

In an embodiment, the first airflow generating unit includes a plurality of first airflow generating members; in a same first airflow generating unit, all the first airflow generating members are stacked in the direction in which the first cavity points to the second cavity; or in the same first airflow generating unit, all the first airflow generating members are arranged side by side, and air outlet directions of all the first airflow generating members are parallel to each other and in a same direction.

In an embodiment, at least one second vent is provided, the airflow generator includes at least one second airflow generating unit, and inlets of the second airflow generating units and the second vents are communicated in one-to-one correspondence; and/or the power conversion system further includes a flow guiding member located in the first cavity; and an inlet of the first airflow generating unit is in communication with the corresponding first vent via the flow guiding member.

In an embodiment, the liquid cooling member includes a plurality of liquid cooling units sequentially connected along a circulating direction of a medium; and along the first direction, all the liquid cooling units are sequentially arranged.

In an embodiment, the liquid cooling unit located most upstream along the first direction is defined as a first liquid cooling unit; the first liquid cooling unit includes a plurality of first liquid cooling portions arranged in series along the circulating direction of the medium; and/or

[symbol]

In an embodiment, the liquid cooling unit located most downstream along the first direction is defined as a second liquid cooling unit; the second liquid cooling unit includes a plurality of second liquid cooling portions arranged in series along the circulating direction of the medium; and/or at least one liquid cooling unit between the liquid cooling unit located most upstream and the liquid cooling unit located most downstream along the first direction is defined as a third liquid cooling unit; the third liquid cooling unit includes a plurality of third liquid cooling portions arranged side by side in a direction perpendicular to the first direction.

In an embodiment, along the first direction, the liquid cooling unit between the liquid cooling unit located most upstream and the liquid cooling unit located most downstream defines at least one first gap in communication with the second cavity; and the at least one first gap has a target gap, and the partition wall is provided with an opening in communication with the target gap in a region located in the target gap.

In an embodiment, the power conversion system further includes a printed circuit board (PCB) arranged in the first cavity, and a plurality of electronic components arranged on the PCB; and a second gap in communication with the opening is defined between the PCB and the partition wall.

In an embodiment, the power conversion system further includes a plurality of radiating fins; all the radiating fins are located in the second cavity and are arranged on the partition wall; at least part of the radiating fins are arranged in rows along the first direction and are arranged in columns along a fourth direction; and the first direction, the fourth direction, and the direction in which the first cavity points to the second cavity intersect with each other; and/or a liquid inlet and a liquid outlet of the liquid cooling member are both arranged adjacent to one of the two first sides.

In an embodiment, the second cavity is located on a bottom side of the first cavity, and the direction in which the first cavity points to the second cavity is a direction of gravity.

According to another aspect of the present disclosure, embodiments of the present disclosure provide an energy storage system, including the power conversion system in any one of the above embodiments.

In the power conversion system and the energy storage system, the power conversion system includes at least a tank, a heat exchanger, and an airflow generator. A partition wall is arranged in a body of the tank to form a first cavity and a second cavity, the first cavity and the second cavity are communicated via vents provided in the partition wall, the airflow generator is arranged in the first cavity, and a liquid cooling member is arranged in the second cavity. In this way, main heat-generating components can be placed in the first cavity, and the components in the first cavity can be cooled via the liquid cooling member in the second cavity. Under the action of the airflow generator, gas in the first cavity can exchange heat with gas in the second cavity via the vents, and the gas in the second cavity and the liquid cooling member located in the second cavity can be further utilized, which helps improve heat dissipation efficiency of the main heat-generating components in the first cavity, and also helps reduce a risk of condensation on related components via flowing of gas between the first cavity and the second cavity. At the same time, due to the heat exchange with the gas in the first cavity via the gas in the second cavity, extra space in the first cavity may not be occupied, which is conducive to arrangement of the related components in the first cavity. Therefore, the apparatus provided in the embodiments of the present disclosure can improve the heat dissipation effect when space is limited, and can also improve safety performance.

Additional aspects and advantages of the embodiments of the present disclosure will be set forth in part in the description below, and in part will be apparent from the description, or learned through practice of the embodiments of the present disclosure.

### BRIEF DESCRIPTION OF THE DRAWINGS

Various other advantages and benefits will become apparent to those of ordinary skill in the art upon reading the following detailed description of the embodiments. The drawings are only for the purpose of illustrating the embodiments and are not to be considered as limitations on the present disclosure. Moreover, same members are represented by same reference numerals throughout the drawings. In the drawings:

FIG. 1 is a perspective view of a power conversion system according to some embodiments of the present disclosure;

FIG. 2 is an exploded view of the power conversion system according to some embodiments of the present disclosure;

FIG. 3 is a perspective view of the power conversion system according to some embodiments of the present disclosure;

FIG. 4 is a side view of the power conversion system according to some embodiments of the present disclosure;

FIG. 5 is a perspective view of the power conversion system from which a body is removed according to some embodiments of the present disclosure;

FIG. 6 is a top-view structure of the power conversion system from which the body is removed according to some embodiments of the present disclosure;

FIG. 7 is a bottom-view structure of the power conversion system from which the body is removed according to some embodiments of the present disclosure;

FIG. 8 is a schematic view of a relationship between projections of first vents and projections of second vents according to some embodiments of the present disclosure;

FIG. 9 is a perspective view of the power conversion system from which the body is removed according to some other embodiments of the present disclosure;

FIG. 10 is a perspective view of the power conversion system from which the body is removed according to some other embodiments of the present disclosure;

FIG. 11 is a perspective view of the power conversion system from which the body is removed according to some other embodiments of the present disclosure;

FIG. 12 is a perspective view of the power conversion system from which the body is removed according to some other embodiments of the present disclosure;

FIG. 13 is a schematic view of a liquid cooling member according to some embodiments of the present disclosure;

FIG. 14 is a side view of the power conversion system from which the body is removed according to some embodiments of the present disclosure; and

FIG. 15 is a perspective view of the structure in FIG. 14.

### REFERENCE SIGNS

power conversion system 100;
tank 110, body 111, first part 111a, second part 111b, partition wall 112, first side b1, second side b2, corner portion c, first corner portion c1, second corner portion c2, third corner portion c3, fourth corner portion c4, vent k1, first vent k1a, second vent k1b, opening k2, first cavity Q1, second cavity Q2;
liquid cooling member 120, liquid cooling unit 121, first liquid cooling unit 121a, first liquid cooling portion L1, second liquid cooling unit 121b, second liquid cooling portion L2, third liquid cooling unit 121c, third liquid cooling portion L3, first gap g1, connecting structure 122, liquid inlet j1, liquid outlet j2;
airflow generator 130, first airflow generating unit 131, first airflow generating member 1311;
flow guiding member 140;
PCB 150, second gap g2;
electronic component 160;
radiating fin 170;
reference plane E, first projection y1, second projection y2;
first direction F1, second direction F2, third direction F3.

### DETAILED DESCRIPTION OF THE EMBODIMENTS

In order to make the above objectives, features, and advantages of the present disclosure more obvious and understandable, specific implementations of the present disclosure are described in detail below with reference to the accompanying drawings. In the following description, many specific details are set forth in order to fully understand the present disclosure. However, the present disclosure can be implemented in many other ways different from those described herein, and those skilled in the art can make similar improvements without departing from the connotation of the present disclosure. Therefore, the present disclosure is not limited by specific embodiments disclosed below.

In the description of the present disclosure, it is to be understood that the orientation or position relationships indicated by the terms “central”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, “axial”, “radial”, “circumferential”, and the like are based on the orientation or position relationships shown in the accompanying drawings and are intended to facilitate the description of the present disclosure and simplify the description only, rather than indicating or implying that the apparatus or element referred to must have a particular orientation or be constructed and operated in a particular orientation, and therefore are not to be interpreted as limiting the present disclosure.

In addition, the terms “first” and “second” are used for descriptive purposes only, which cannot be construed as indicating or implying a relative importance, or implicitly specifying the number of the indicated technical features. Therefore, the features defined with “first” and “second” may explicitly or implicitly include at least one feature. In the description of the present disclosure, “a plurality of” means at least two, such as two or three, unless otherwise defined explicitly and specifically.

In the present disclosure, unless otherwise specified and defined explicitly, the terms “mount”, “connect”, “join”, and “fix” should be understood in a broad sense, which may be, for example, a fixed connection, a detachable connection, or an integral connection; a mechanical connection or an electrical connection; or a direct connection, an indirect connection via an intermediate medium, an internal connection between two elements, or interaction between two elements. Those of ordinary skill in the art can understand specific meanings of these terms in the present disclosure according to specific situations.

In the present disclosure, unless otherwise explicitly specified and defined, the expression a first feature being “on” or “under” a second feature may be the case that the first feature is in direct contact with the second feature, or the first feature is in indirect contact with the second feature via an intermediate medium. Furthermore, the expression the first feature being “over”, “above” and “on top of” the second feature may be the case that the first feature is directly above or obliquely above the second feature, or only means that the level of the first feature is higher than that of the second feature. The expression the first feature being “below”, “underneath” or “under” the second feature may be the case that the first feature is directly underneath or obliquely underneath the second feature, or only means that the level of the first feature is lower than that of the second feature.

It is to be noted that when one element is referred to as being “fixed to” or “arranged on” another element, it may be directly disposed on the other element or an intermediate element may exist. When one element is considered to be “connected to” another element, it may be directly connected to another element or an intermediate element may co-exist. The terms “vertical”, “horizontal”, “left”, “right” and similar expressions used herein are for illustrative purposes only and do not represent an only implementation.

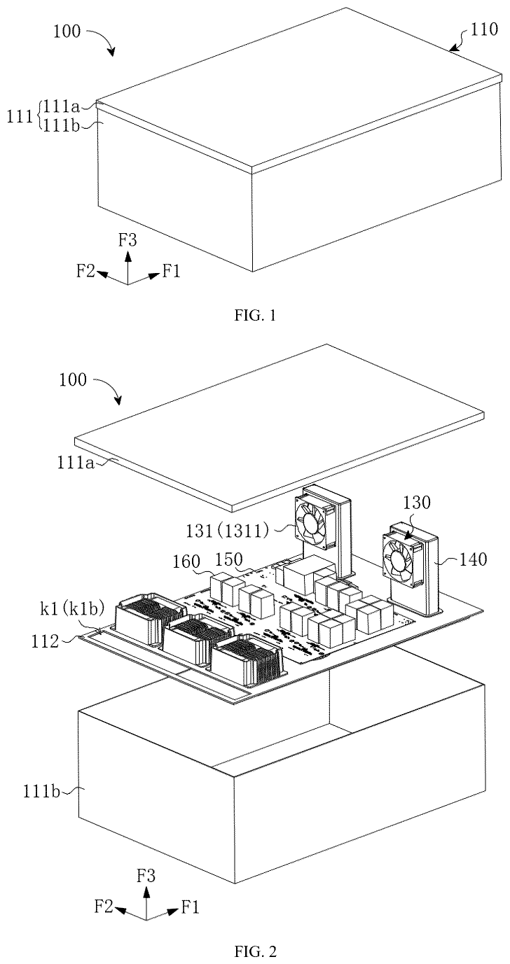

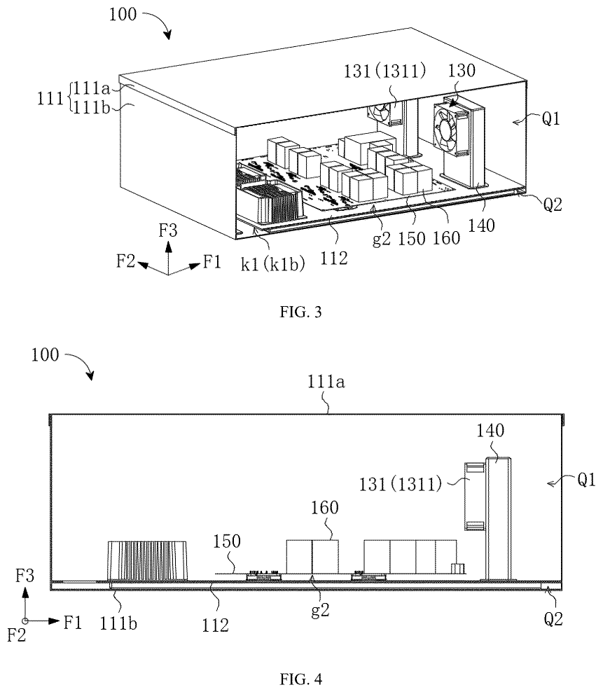

FIG. 1 is a perspective view of a power conversion system 100 according to some embodiments of the present disclosure; FIG. 2 is an exploded view of the power conversion system 100 according to some embodiments of the present disclosure; FIG. 3 is a perspective view of the power conversion system 100 according to some embodiments of the present disclosure; and FIG. 4 is a side view of the power conversion system 100 according to some embodiments of the present disclosure. For ease of description, only content related to the embodiments of the present disclosure is illustrated.

Referring to FIG. 1 to FIG. 4, embodiments of the present disclosure provide an power conversion system 100, including a tank 110, a liquid cooling member 120, and an airflow generator 130.

The tank 110 has an accommodation cavity. The accommodation cavity is configured to accommodate related components of the power conversion system 100, which can ameliorate an influence of foreign matter on use of the related components in the power conversion system 100. The tank 110 may have a simple three-dimensional structure such as a single cuboid or a complex three-dimensional structure formed by simple three-dimensional structures such as cuboids, which is not limited herein. In the embodiments of the present disclosure, taking FIG. 1 as an example, the tank 110 has a shape of a cuboid. A first direction F1 and a second direction F2 are a length direction and a width direction of the tank 110, respectively, and a third direction F3 is a height direction of the tank 110. A dimension of the tank 110 along the length direction and a dimension of the tank 110 along the width direction may or may not be equal. The first direction F1, the second direction F2, the third direction F3 are perpendicular to each other.

The tank 110 includes a body 111 and a partition wall 112 arranged in the body 111. The partition wall 112 divides an interior of the body 111 into a first cavity Q1 and a second cavity Q2. The partition wall 112 is provided with a plurality of vents k1. The vents k1 are communicated between the first cavity Q1 and the second cavity Q2.

For example, referring to FIG. 1 and FIG. 2, the body 111 forms a main part of the tank 110. The body 111 includes a first part 111a and a second part 111b. The first part 111a and the second part 111b cover each other, and the first part 111a and the second part 111b cooperatively define the aforementioned accommodation cavity. The second part 111b may have a hollow structure with one end opened. The first part 111a may have a plate-like structure, and the first part 111a covers an opening side of the second part 111b, so that the first part 111a and the second part 111b cooperatively define the accommodation cavity. The first part 111a and the second part 111b may alternatively have hollow structures with one side opened, and the open side of the first part 111a covers the opening side of the second part 111b. Certainly, the tank 110 formed by the first part 111a and the second part 111b may be in a variety of shapes, such as a cylinder or a cuboid.

Referring to FIG. 3 and FIG. 4, the partition wall 112 divides the accommodation cavity into the first cavity Q1 and the second cavity Q2. That is, the accommodation cavity includes the first cavity Q1 and the second cavity Q2 that are separated from each other. The first cavity Q1 and the second cavity Q2 are communicated via the vent k1. The partition wall 112 and the body 111 may be of an integrated structure or separated structure. The integrated structure refers to a structure formed by connecting two components into an entirety, and the two components are no longer two separate components. For example, the partition wall 112 and the body 111 may be connected by welding, hot melt welding, or integrated molding. Integrated molding means that a whole component is formed by the same material through an integrated molding process. The separated structure refers to a structure in which two components are fixedly connected through a related connector. A selection may be made according to a specific usage condition, which is not specifically limited herein. Further, the partition wall 112 may be a board. Certainly, the partition wall 112 may be two boards stacked along the third direction F3. The structure of the partition wall 112 may be arranged according to a specific usage condition, which is not specifically limited herein.

The first cavity Q1 may be configured to receive a main electronic component 160 and other components (such as an inductor, a power module, and a heat sink) used in conjunction with the main electronic component 160. The second cavity Q2 may be configured to receive the liquid cooling member 120. The first cavity Q1 may be configured as a closed structure, which can protect the electronic components 160, so that the electronic components 160 are in a relatively stable and dry environment. In this way, the liquid cooling member 120 may not occupy additional mounting space of the electronic component 160, making the overall structure more compact. It should be understood that the closed structure defined by the first cavity Q1 is relative to the vent k1 on the partition wall.

The liquid cooling member 120 is a component for heat dissipation. The liquid cooling member 120 takes away heat through liquid circulation. Liquid flows in a channel inside the liquid cooling member 120 and comes into contact with the partition wall 112. After absorbing heat transferred from the electronic components 160 to the partition wall 112, the liquid carries the heat to a related cooling device, which, after cooling, circulates back to the vicinity of the partition wall 112 to continue absorbing heat, and so on, to achieve continuous heat dissipation. Compared with conventional air cooling heat dissipation manners, the liquid cooling member 120 has higher heat dissipation efficiency, higher stability, and occupies less space. For example, the liquid serving as a cooling medium may be liquid such as water or oil. A selection may be made according to a specific usage condition, which is not specifically limited herein.

The airflow generator 130 is arranged in the first cavity Q1. The airflow generator 130 is configured to input gas located in the second cavity Q2 into the first cavity Q1 via at least one of the vents k1 and output gas located in the first cavity Q1 into the second cavity Q2 via at least another one of the vents k1. In this way, the heat exchange of the gas in the first cavity Q1 and the second cavity Q2 can be achieved via the vent k1 and the airflow generator 130.

The airflow generator 130 is a component configured to generate airflow. Specifically, the first airflow generator 130 may be a fan assembly, and rotation of fan blades can drive the gas in the first cavity Q1 to enter the second cavity Q2 and to exchange heat with the gas in the second cavity Q2, reducing an internal temperature of the first cavity Q1. Certainly, the airflow generator 130 may alternatively be another component that can generate an airflow such as a blower.

In the embodiments of the present disclosure, the partition wall 112 is arranged in a body 111 of the tank 110 to form the first cavity Q1 and the second cavity Q2, and the first cavity Q1 and the second cavity Q2 are communicated via vents k1 provided in the partition wall 112. The airflow generator 130 is arranged in the first cavity Q1, and the liquid cooling member 120 is arranged in the second cavity Q2. In this way, main heat-generating components can be placed in the first cavity Q1, and the components in the first cavity can be cooled via the liquid cooling member 120 in the second cavity Q2. Under the action of the airflow generator 130, gas in the first cavity Q1 can exchange heat with gas in the second cavity Q2 via the vents k1, and the gas in the second cavity Q2 and the liquid cooling member 120 located in the second cavity Q2 can be further utilized, which helps to improve heat dissipation efficiency of the main heat-generating components in the first cavity Q1, and also helps to reduce a risk of condensation on related components via flowing of gas between the first cavity Q1 and the second cavity Q2. At the same time, due to the heat exchange with the gas in the first cavity Q1 via the gas in the second cavity Q2, extra space in the first cavity Q1 may not be occupied, which is conducive to arrangement of the related components in the first cavity Q1. Therefore, the apparatus provided by the embodiments of the present disclosure can improve the heat dissipation effect when space is limited, and can also improve safety performance.

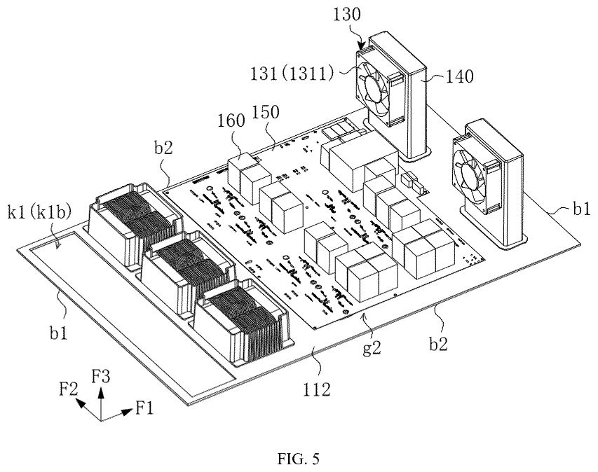

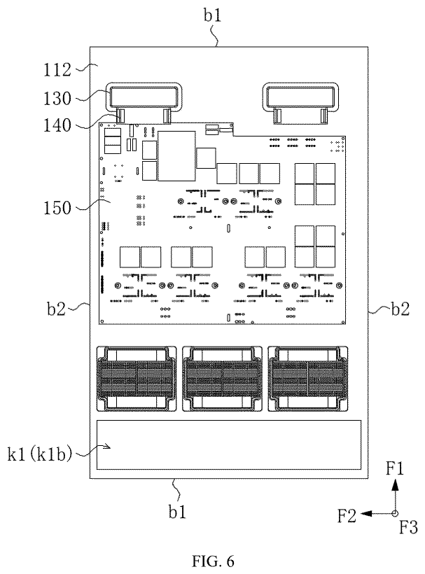

FIG. 5 is a perspective view of the power conversion system 100 from which the body 111 is removed according to some embodiments of the present disclosure; and FIG. 6 is a top view of the power conversion system 100 from which the body 111 is removed according to some embodiments of the present disclosure. For ease of description, only content related to the embodiments of the present disclosure is illustrated.

In some embodiments, still referring to FIG. 3 and FIG. 4, together with FIG. 5 and FIG. 6, the partition wall 112 has two first sides b1 oppositely arranged along the first direction F1, and the first direction F1 intersects with a direction in which the first cavity Q1 points to the second cavity Q2. All the vents k1 are arranged adjacent to the two first sides b1 respectively, and all the vents k1 are configured to cooperate with the airflow generator 130 to form an annular airflow that circulates from the first cavity Q1 to the second cavity Q2.

In the embodiments of the present disclosure, the direction in which the first cavity Q1 points to the second cavity Q2 and the third direction F3 are parallel to each other. That is, the direction in which the first cavity Q1 points to the second cavity Q2 and the first direction F1 are perpendicular to each other.

It should be understood that, taking FIG. 3 and FIG. 4 as an example, to enable heat dissipation of the electronic components 160 in the first cavity Q1 more uniform, generally, the gas in the first cavity Q1 may form a circumferential annular airflow surrounding an inner wall of the second part 111b in the first cavity Q1, so that the gas can be in contact with surfaces of the electronic components 160 more evenly, thereby improving heat exchange efficiency. However, the inventor finds that since the first cavity Q1 and the second cavity Q2 have different heights in the third direction F3, by forming a circulating annular airflow between the first cavity Q1 and the second cavity Q2, the gas can be more fully mixed and exchanged between cavities at different heights. Compared with the manner in which the circumferential annular airflow is in the first cavity Q1, such circulation in the first cavity Q1 and the second cavity Q2 can promote transferring of heat in the third direction F3, thus enabling the heat to be transferred from the first cavity Q1 to the second cavity Q2 more quickly, thereby improving the overall heat exchange efficiency.

Further, since the gas circulates between the first cavity Q1 and the second cavity Q2, the heat can be more widely spread to different positions, which reduces an excessively high or excessively low local temperature, also reduces gas retention and vortex phenomena in the first cavity Q1, makes the flowing of the gas smoother, and can reduce local flow resistance and instability factors, thereby improving reliability and stability. Therefore, the formation of the annular airflow between the first cavity Q1 and the second cavity Q2 helps to make distribution of temperatures more uniform throughout the power conversion system 100.

In addition, the electronic components 160 in the first cavity Q1 generally have different heights. Since the annular airflow between the first cavity Q1 and the second cavity Q2 is formed via the first cavity Q1 and the second cavity Q2 having different heights, the heights of the electronic components 160 in the first cavity Q1 can be better matched, and heat generated by the electronic components 160 can be taken away in a more timely manner. That is, the annular airflow between the first cavity Q1 and the second cavity Q2 can adapt to more complex structures and layouts. In this way, the arrangement of the electronic components 160 in the first cavity Q1 can also be more flexible, thereby also meeting different usage requirements.

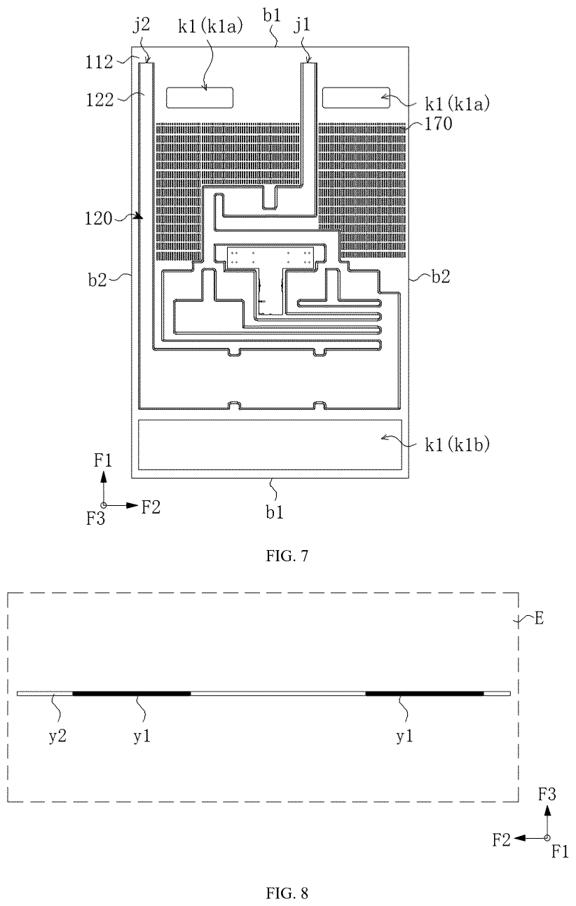

FIG. 7 is a bottom-view of the power conversion system 100 from which the body 111 is removed according to some embodiments of the present disclosure. For ease of description, only content related to the embodiments of the present disclosure is illustrated.

In some embodiments, still referring to FIG. 5 and FIG. 6 together with FIG. 7, in all the vents k1, the vents k1 for air inlet are defined as first vents k1a, and vents k1 for air outlet are defined as second vents k1b. The airflow generator 130 includes at least one first airflow generating unit 131, and inlets of the first airflow generating units 131 and the first vents k1a are communicated in one-to-one correspondence. That is, the airflow generation manner of the first airflow generating unit 131 is air extraction. Taking FIG. 5 to FIG. 7 as an example, two first airflow generating units 131 and two first vents k1a are provided, and the two first airflow generating units 131 and the two first vents k1a are arranged in one-to-one correspondence.

By setting the airflow generation manner of the first airflow generating unit 131 to air extraction, under the action of the first airflow generating unit 131, the gas in the second cavity Q2 is drawn into the first cavity Q1 through the first vent k1a and exchanges heat with the gas in the first cavity Q1. At the same time, since the second vent k1b can cooperate with the first vent k1a to form the annular airflow between the first cavity Q1 and the second cavity Q2, the gas in the first cavity Q1 can enter the second cavity Q2 from the second vent k1b under the action of one airflow generating unit and continue to exchange heat with the gas in the second cavity Q2. In this way, heat exchange between the gas in the first cavity Q1 and the gas in the second cavity Q2 is realized.

In this process, since the airflow generation manner of the first airflow generating unit 131 is air extraction, the gas flowing through the first airflow generating unit 131 is a gas with a lower temperature, which is conducive to prolonging the service life of the first airflow generating unit 131, thereby improving reliability of the first airflow generating unit 131.

In some embodiments, still referring to FIG. 5 to FIG. 7, a plurality of first vents k1a and a plurality of first airflow generating units 131 are provided. All the first vents k1a are arranged adjacent to one of the first sides b1, and the second vents k1b are arranged adjacent to the other of the first sides b1.

In this way, a path of movement of the annular airflow between the first cavity Q1 and the second cavity Q2 can be extended as much as possible, thereby further improving the heat exchange efficiency of the gases in the first cavity Q1 and the second cavity Q2.

FIG. 8 is a schematic view showing a relationship between projections of first vents and projections of second vents according to some embodiments of the present disclosure. For ease of description, only content related to the embodiments of the present disclosure is illustrated.

In some embodiments, still referring to FIG. 5 to FIG. 7 together with FIG. 8, one second vent k1b is provided. Orthographic projections of all the first vents k1a on a reference plane E are located within a range of an orthographic projection of the second vent k1b on the reference plane E. The reference plane E is a plane perpendicular to a direction in which the first side b1 points to the second side b2. In the embodiments of the present disclosure, the direction in which the first side b1 points to the second side b2 is the first direction F1.

Taking FIG. 8 as an example, an orthographic projection of the first vent k1a on the reference plane E is a first projection y1, and an orthographic projection of the second vent k1b on the reference plane E is a second projection y2. The two first projections y1 are within a range of the second projection y2.

One second vent k1b is provided and the second vent k1b can correspond to all the first vents k1a as much as possible, so that the second vent k1b can generally correspond to an annular path of the annular airflow formed between the first cavity Q1 and the second cavity Q2. In this way, it is conducive to forming the above annular airflow, and a plurality of first vents k1a can be flexibly arranged at different positions according to actual usage requirements, thereby adapting to various complex spatial structures and layouts. At the same time, the plurality of first vents k1a can extract air from different positions and can cover a larger spatial range, and a larger second vent k1b can not only reduce an influence of airflow fluctuations on the formation of the annular airflow, but also can reduce resistance of the gas from the first cavity Q1 into the second cavity Q2, which is more conducive to the heat exchange between the gases in the first cavity Q1 and the second cavity Q2.

In some embodiments, still referring to FIG. 5 to FIG. 7, all the first vents k1a are sequentially spaced apart along a preset direction. The preset direction, the first direction F1, and the direction in which the first cavity Q1 points to the second cavity Q2 are perpendicular to each other. In the embodiments of the present disclosure, the preset direction is the second direction F2.

In this way, air extraction can be performed at roughly the same reference position, which helps to reduce airflow fluctuations. At the same time, two adjacent first vents k1a are arranged at intervals, which helps to improve uniformity of air extraction.

In some embodiments, still referring to FIG. 5 to FIG. 7, an outlet of the first airflow generating unit 131 is arranged towards the second vent k1b, and the outlet of the first airflow generating unit 131 is oriented parallel to the first direction F1.

Compared with the manner in which the outlet of the first airflow generating unit 131 is inclined relative to the second vent k1b, a gas blown by the first airflow generating unit 131 can move towards the second vent k1b, which is conducive to improving utilization of the gas, further ameliorating airflow fluctuations, and forming an annular airflow between the first cavity Q1 and the second cavity Q2.

In some embodiments, still referring to FIG. 5 and FIG. 6, two first vents k1a and two first airflow generating units 131 are provided. One of the first vents k1a is arranged adjacent to one end of one of the first sides b1, and the other first vents k1a is arranged adjacent to the other end of the one of the first sides b1.

In this way, the generated airflow can be guided to flow into the second vent k1b via two inner walls of the first cavity Q1 that are oppositely arranged along the second direction F2, and a velocity of the airflow can also be increased via friction between the two inner walls of the first cavity Q1 that are oppositely arranged along the second direction F2 and the airflow. In this way, two annular airflows can be roughly formed between the first cavity Q1 and the second cavity Q2. The two annular airflows can limit lateral diffusion of the gas in a region between the two vents k1 to some extent, and can enable the gas in the region between the two vents k1 to flow more stably in the first direction F1.

In this process, due to existence of a gap between the two annular airflows, the gas in a middle region can be squeezed to some extent in the second direction F2, making an airflow velocity more evenly distributed in the middle region. Under constraints of the gap between the two annular airflows, the gas in the middle region flows more effectively into the second vent k1b along the first direction F1, which improves gas transport efficiency and reduces energy loss. It should be understood that the two annular airflows can provide a clearer flow channel and direction guidance for the gas in the middle region. The gas in the middle region may be more inclined to flow along a direction defined by the two annular airflows in a “sandwich” situation formed by the two annular airflows. Therefore, on the whole, the gas extracted from the second cavity Q2 to the first cavity Q1 flows into the second vent k1b along the first direction F1 and then flows into the second cavity Q2, which is conducive to improving the heat exchange efficiency of the gases in the first cavity Q1 and the second cavity Q2.

It should to be noted that the above two annular airflows and an airflow formed by the gas in the middle region are only for illustrating a circulating direction of the gas inside the power conversion system 100. In actual use, the gases in different regions are not significantly distinguished, but generally flow according to the above process. That is, on the whole, the annular airflow is formed between the first cavity Q1 and the second cavity Q2.

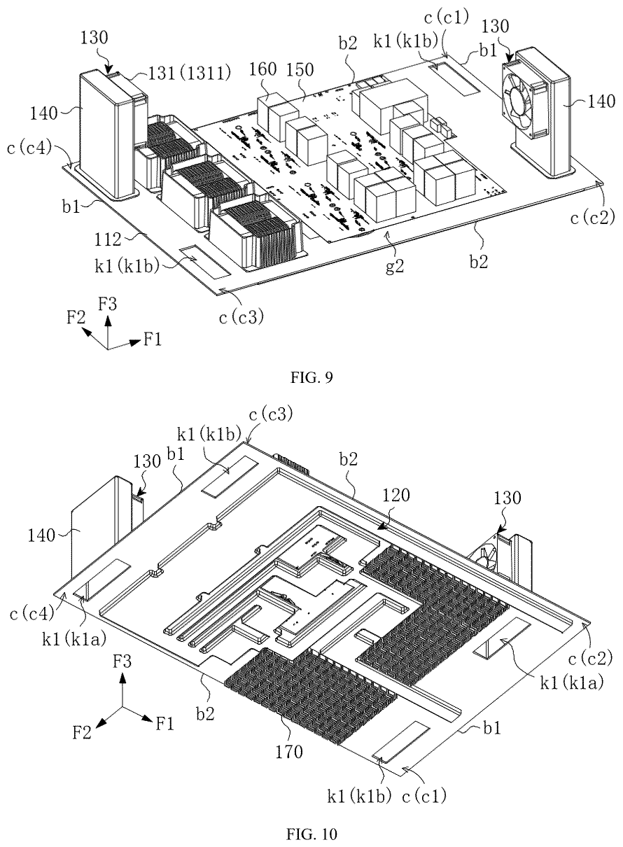

FIG. 9 is a top-view of the power conversion system 100 from which the body 111 is removed according to some other embodiments of the present disclosure; and FIG. 10 is a bottom-view of the power conversion system 100 from which the body 111 is removed according to some other embodiments of the present disclosure. For ease of description, only content related to the embodiments of the present disclosure is illustrated.

In some embodiments, referring to FIG. 9 and FIG. 10, the partition wall 112 further has two second sides b2 oppositely arranged along the second direction F2. Each first side b1 is connected to the two second sides b2, and each first side b1 and the two second sides b2 define two corner portions c. The first direction F1, the second direction F2, and the direction in which the first cavity Q1 points to the second cavity Q2 are perpendicular to each other. A plurality of first vents k1a, a plurality of second vents k1b, and a plurality of first airflow generating units 131 are provided. At least one of the first airflow generating units 131 is arranged at a first target corner portion, and the rest of the first airflow generating units 131 are located at a second target corner portion. The first target corner portion and the second target corner portion are two corner portions c in all the corner portions c and not adjacent along a circumferential direction of the partition wall 112. At least one of the second vents k1b is located on an air outlet path of at least one of the first airflow generating units 131, and the rest of the second vents k1b are located on air outlet paths of the rest of the first airflow generating units 131.

Taking FIG. 9 and FIG. 10 as an example, the partition wall 112 generally has a plate-shaped structure in a longitudinal direction, and the four corner portions c are a first corner portion c1, a second corner portion c2, a third corner portion c3, and a fourth corner portion c4, respectively. The second corner portion c2 is a first target corner portion, and the fourth corner portion c4 is a second target corner portion. One second vent k1b is located at the first corner portion c1, and the other second vent k1b is located at the third corner portion c3.

Taking the situation illustrated in FIG. 9 and FIG. 10 as an example, the gas extracted from the second cavity Q2 by the first airflow generating unit 131 located at the fourth corner portion c4 via the first vent k1a may flow into the second cavity Q2 from the second vent k1b located at the first corner portion c1, and a formed annular airflow flows into the second vent k1b along the first direction F1 in the first cavity Q1, and flows into the first vent k1a along a direction opposite to the first direction F1 in the second cavity Q2. The gas extracted from the second cavity Q2 by the first airflow generating unit 131 located at the second corner portion c2 via the first vent k1a may flow into the second cavity Q2 from the second vent k1b located at the third corner portion c3, and a formed annular airflow flows into the second vent k1b along a direction opposite to the first direction F in the first cavity Q1, and flows into the second vent k1b along the first direction F1 in the second cavity Q2. In this way, two annular airflows in opposite directions can be roughly formed. The “two annular airflows in opposite directions” means that one of the annular airflows flows clockwise and the other annular airflow flows counterclockwise.

Due to the reverse movement of the two annular airflows, a certain pressure balance effect may be achieved between the two annular airflows, and the pressure balance can enhance stability of the airflow in the middle region. Further, the two annular airflows may generate opposite forces on the airflow in the middle region, which can promote continuous mixing and exchange between the airflow in the middle region and the two annular airflows and ameliorate air agglomeration in a local region in the first cavity Q1. In this way, adequacy and efficiency of heat exchange of gases between the first cavity Q1 and the second cavity Q2 are further improved.

It should be understood that the formation of the two annular airflows in opposite directions described above may alternatively be considered by referring to the arrangement shown in FIG. 5. For example, one first airflow generating unit 131 is arranged adjacent to one second side b2, and another first airflow generating unit 131 is arranged adjacent to the other second side b2. In this way, a velocity of the airflow can be further increased via two side walls of the first cavity Q1 along the second direction F2. Correspondingly, the two second vents k1b can also be considered in this manner. Details are not described herein again.

In this way, by arranging each first airflow generating unit 131 and each vent k1 at corresponding positions, two annular airflows in opposite directions can be formed, which is conducive to further improving the heat exchange effect.

In some embodiments, still referring to FIG. 9 and FIG. 10, in the four corner portions c, the corner portions c other than the first target corner portion and the second target corner portion are a third target corner portion and a fourth target corner portion. An outlet of at least one of the first airflow generating units 131 is arranged towards the third target corner portion. At least one of the second vents k1b is arranged at the third target corner portion. Outlets of the rest of the first airflow generating units 131 are arranged toward the fourth target corner portion, and the rest of the second vents k1b are arranged at the fourth target corner portion.

Taking FIG. 9 and FIG. 10 as an example, the third target corner portion is the first corner portion c1, and the fourth target corner portion is the third corner portion c3. The outlet of the first airflow generating unit 131 located at the fourth corner portion c4 is arranged towards the first corner portion c1, and the outlet of the first airflow generating unit 131 located at the second corner portion c2 is arranged towards the third corner portion c3.

Compared with the manner in which the outlet of the first airflow generating unit 131 is inclined relative to the second vent k1b, a gas blown by the first airflow generating unit 131 can move towards the second vent k1b, which is conducive to improving utilization of the gas, further ameliorating airflow fluctuations, and forming an annular airflow between the first cavity Q1 and the second cavity Q2.

In some embodiments, still referring to FIG. 9 to FIG. 10, two first vents k1a, two second vents k1b, and two first airflow generating units 131 are provided. In this way, the gases in the first cavity Q1 and the second cavity Q2 can perform heat exchange, and the space occupied in the first cavity Q1 can be reduced.

Certainly, in some other embodiments, the numbers of the first vents k1a, the second vents k1b, and the first airflow generating units 131 may be alternatively configured according to actual usage conditions, which is not specifically limited herein.

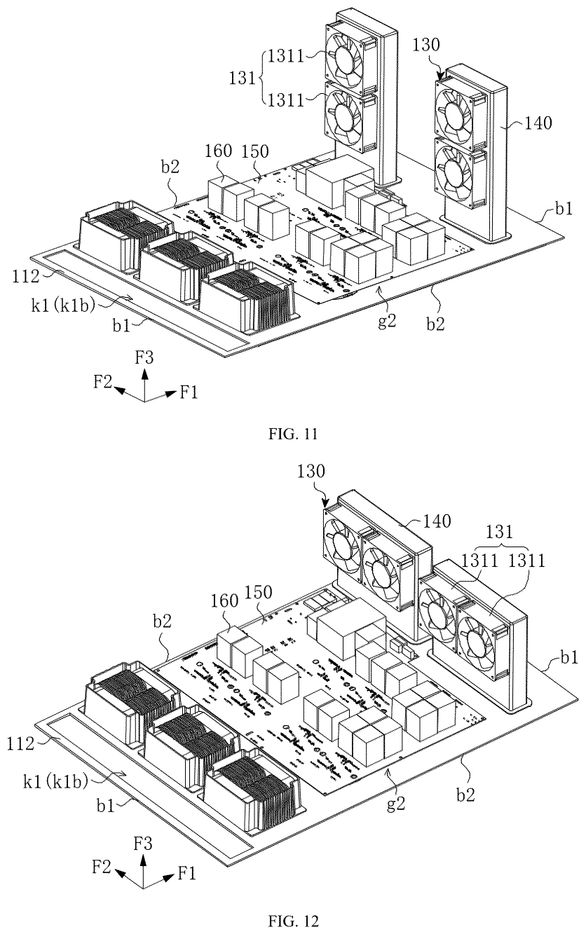

FIG. 11 is a perspective view of the power conversion system 100 from which the body 111 is removed according to some other embodiments of the present disclosure; and FIG. 12 is a perspective view of the power conversion system 100 from which the body 111 is removed according to some other embodiments of the present disclosure. For ease of description, only content related to the embodiments of the present disclosure is illustrated.

In some embodiments, referring to FIG. 11 and FIG. 12, the first airflow generating unit 131 includes a plurality of first airflow generating members 1311. In the same first airflow generating unit 131, all the first airflow generating members 1311 are stacked in the direction in which the first cavity Q1 points to the second cavity Q2. Alternatively, in the same first airflow generating unit 131, all the first airflow generating members 1311 are arranged side by side, and air outlet directions of all the first airflow generating members 1311 are parallel to each other and in the same direction.

Taking FIG. 11 as an example, the first airflow generating unit 131 includes two first airflow generating members 1311, and the two first airflow generating members 1311 in the same first airflow generating unit 131 are stacked along the third direction F3. Taking FIG. 12 as an example, the first airflow generating unit 131 includes two first airflow generating members 1311, and the two first airflow generating members 1311 in the same first airflow generating unit 131 are arranged side by side along the second direction F2. Certainly, in the situation illustrated in FIG. 9 and FIG. 10, the arrangement manner of the first airflow generating members 1311 illustrated in FIG. 11 and FIG. 12 may be alternatively adopted.

In this way, through the arrangement of the plurality of first airflow generating members 1311 in the first airflow generating unit 131, the amount of the airflow can be improved, thereby further increasing the velocity of the airflow and improving efficiency of heat exchange. The numbers of the first airflow generating members 1311 may be configured according to a specific usage condition, which is not specifically limited herein.

In some embodiments, at least one second vent k1b is provided, the airflow generator 130 includes at least one second airflow generating unit (not shown), and inlets of the second airflow generating units and the second vents k1b are communicated in one-to-one correspondence.

It is to be noted that velocities of the gases in the first cavity Q1 and the second cavity Q2 can be further increased via the second airflow generating unit. It is to be noted that the second airflow generating unit may be arranged according to an actual usage requirement, which is not specifically limited herein. Without the second airflow generating unit, the overall structure can be simpler.

In some embodiments, still referring to FIG. 2 to FIG. 5 and FIG. 9 to FIG. 12, the power conversion system 100 further includes a flow guiding member 140 located in the first cavity Q1. An inlet of the first airflow generating unit 131 is in communication with the corresponding first vent k1a via the flow guiding member 140.

Specifically, the flow guiding member 140 has one end that may cover the corresponding first vent k1a, and the other end that may be in communication with the inlet of the corresponding first airflow generating unit 131.

In this way, through the arrangement of the flow guiding member 140, the gas extracted from the second cavity Q2 can be guided to the inlet of the corresponding first airflow generating unit 131 to further improve a flow state of the gas and improve efficiency of gas flow.

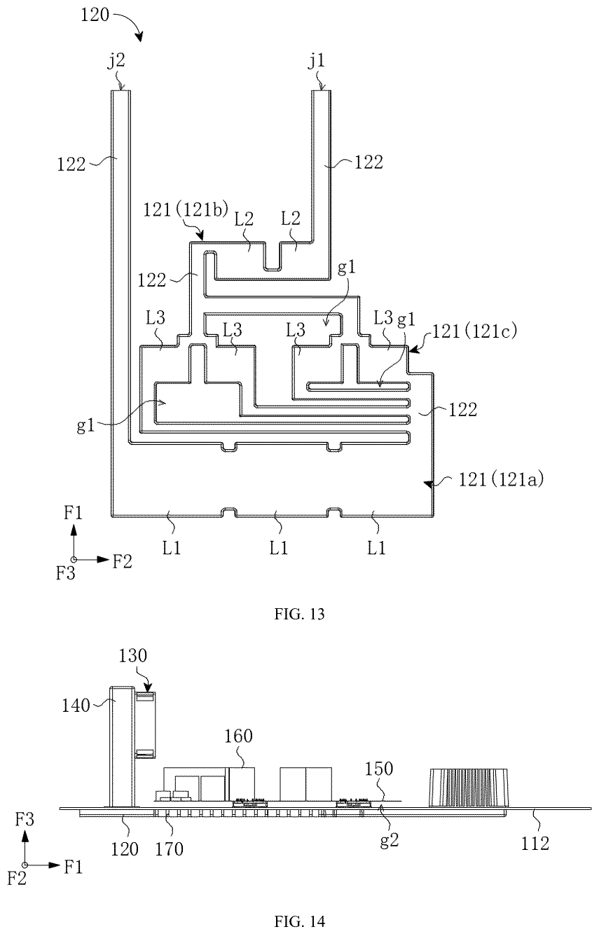

FIG. 13 is a schematic view of a liquid cooling member 120 according to some embodiments of the present disclosure. For ease of description, only content related to the embodiments of the present disclosure is illustrated.

In some embodiments, still referring to FIG. 7 and FIG. 10 together with FIG. 13, the liquid cooling member 120 includes a plurality of liquid cooling units 121 that are sequentially connected along a circulating direction of a medium. Along the first direction F1, all the liquid cooling units 121 are sequentially arranged.

Combined with the content illustrated in some of the foregoing embodiments, the formed annular airflow generally flows annularly in the first direction F1. In this way, all the liquid cooling units 121 are arranged sequentially along the first direction F1, and the gas located in the second cavity Q2 and the cooling medium in the liquid cooling member 120 can continue to perform heat exchange in the first direction F1, which helps to improve the heat exchange effect. Certainly, the electronic components 160 located in the first cavity Q1 may alternatively perform heat exchange with the liquid cooling member 120 via the partition wall 112.

In some embodiments, still referring to FIG. 7, FIG. 10, and FIG. 13, the liquid cooling unit 121 located most upstream along the first direction F1 is defined as a first liquid cooling unit 121a. The first liquid cooling unit 121a includes a plurality of first liquid cooling portions L1 arranged in series along the circulating direction of the medium. Taking FIG. 13 as an example, three first liquid cooling portions L1 are provided, and the three first liquid cooling portions L1 are sequentially arranged along the second direction F2.

Through the arrangement of the plurality of first liquid cooling portions L1 connected in series, flow resistance of the cooling medium located in the first liquid cooling unit 121a can be reduced, and liquid cooling heat dissipation efficiency and effect can be improved.

In some embodiments, still referring to FIG. 7, FIG. 10, and FIG. 13, the liquid cooling unit 121 located most downstream along the first direction F1 is defined as a second liquid cooling unit 121b. The second liquid cooling unit 121b includes a plurality of second liquid cooling portions L2 arranged in series along the circulating direction of the medium. Taking FIG. 13 as an example, two second liquid cooling portions L2 are provided, and the two second liquid cooling portions L2 are sequentially arranged along the second direction F2.

Through the arrangement of the plurality of second liquid cooling portions L2 connected in series, flow resistance of the cooling medium located in the second liquid cooling unit 121b can be reduced, and the liquid cooling heat dissipation efficiency and effect can be improved.

It should be understood that the first liquid cooling unit 121a and the second liquid cooling unit 121b are more adjacent to an inlet or an outlet of the cooling medium and have little impact on a temperature equalization effect of the electronic components 160. Therefore, the flow resistance of the cooling medium can be reduced by series connection.

In some embodiments, still referring to FIG. 7, FIG. 10, and FIG. 13, at least one liquid cooling unit between the liquid cooling unit 121 located most upstream and the liquid cooling unit 121 located most downstream along the first direction F1 is defined as a third liquid cooling unit 121c. The third liquid cooling unit 121c includes a plurality of third liquid cooling portions L3 arranged side by side in a direction perpendicular to the first direction F1. Taking FIG. 13 as an example, four third liquid cooling portions L3 are provided, and the four third liquid cooling portions2 are sequentially arranged along the second direction F2.

Through the arrangement of a plurality of third liquid cooling unit 121c connected in parallel, the electronic component 160 located in the middle region can be dissipated, which helps to improve temperature uniformity between the electronic components 160.

In this way, combined with mutual cooperation between the first liquid cooling unit 121a, the second liquid cooling unit 121b, and the third liquid cooling unit 121c illustrated in some of the above embodiments, the cooling medium can have a certain velocity while having certain temperature uniformity, and the heat dissipation effect and heat dissipation efficiency can be improved.

In some embodiments, still referring to FIG. 13, the liquid cooling member 120 further includes a plurality of connecting structures 122, the liquid cooling units 121 are in communication with each other via the connecting structures 122. The liquid cooling unit 121 located most upstream may flow into the cooling medium via the corresponding connecting structure 122, and the liquid cooling unit 121 located most downstream may flow into the cooling medium via the corresponding connecting structure 122. That is, a liquid inlet j1 and a liquid outlet j2 of the liquid cooling member 120 may be defined via the corresponding connection structures 122. In the embodiments of the present disclosure, the liquid inlet j1 and the liquid outlet j2 of the liquid cooling member 120 are arranged on the same side of the partition wall 112 along the first direction F1.

In this way, communication between the liquid cooling units 121 can be realized through the arrangement of the connecting structures 122, thereby forming a channel for the cooling medium to flow.

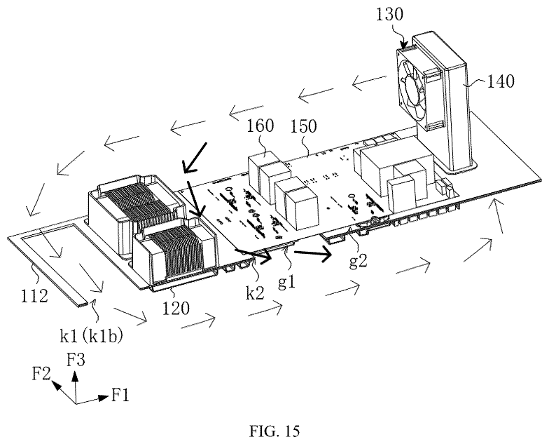

FIG. 14 is a side view of the power conversion system 100 from which the body 111 is removed according to some embodiments of the present disclosure; and FIG. 15 is perspective view structure of the structure in FIG. 14. For ease of description, only content related to the embodiments of the present disclosure is illustrated.

In some embodiments, still referring to FIG. 13 together with FIG. 14 and FIG. 15, along the first direction F1, the liquid cooling unit 121 between the liquid cooling unit 121 located most upstream and the liquid cooling unit 121 located most downstream defines at least one first gap g1 in communication with the second cavity Q2. The at least one first gap g1 has a target gap, and the partition wall 112 is provided with an opening k2 in communication with the target gap in a region located in the target gap.

Taking FIG. 13 as an example, the first gap g1 is defined between the third liquid cooling portions L3 in the third liquid cooling unit 121c, between the third liquid cooling portion L3 and the first liquid cooling unit 121a, and between the third liquid cooling portion L3 and the second liquid cooling unit 121b.

In this way, via the first gap g1 defined by the liquid cooling member 120 and the opening k2 provided in the partition wall 112, the electronic component 160 located in the opening k2 can perform more direct heat exchange with the gas located in the second cavity Q2, which helps to improve the heat dissipation effect of the electronic components 160 located in a central region.

In some embodiments, still referring to FIG. 13 to FIG. 15, the power conversion system 100 further includes a printed circuit board (PCB) 150 arranged in the first cavity Q1, and a plurality of electronic components 160 are arranged on the PCB 150. The PCB 150 and all the electronic components 160 arranged thereon form a printed circuit board assembly (PCBA). A second gap g2 in communication with the opening k2 is defined between the PCB 150 and the partition wall 112.

For example, a dimension of the second gap g2 in the third direction F3 may range from 10 mm to 15 mm, which may be specifically arranged according to an actual usage condition and is not specifically limited herein. For example, the second gap g2 can be controlled according to the electronic components 160 provided on a side of the PCB 150 facing the partition wall 112.

Still referring to FIG. 15, the arrows in FIG. 15 illustrate an approximate main fluid path of the airflow, and the bold arrows indicate that part of the gas flows from the second gap g2 through the opening k2 and the first gap g1 into the second cavity Q2.

In this way, through the arrangement of the first gap g1, the second gap g2, and the opening k2, heat exchange areas of the corresponding electronic components 160 are increased, which can transfer heat to the second cavity Q2 more effectively, thereby improving the heat dissipation efficiency. Since the airflow after the shunt may also form upper and lower circulation, a situation that the heat is concentrated in the local region can be ameliorated, thereby reducing a temperature gradient and making the overall temperature more uniform. Further, the airflow after the shunt can also be switched to balance airflow pressure and enhance airflow circulation, which further facilitates the flow of the gases between the first cavity Q1 and the second cavity Q2. It should be understood that, by controlling positions of the first gap g1, the second gap g2, and the opening k2, layout requirements of different electronic components 160 can be flexibly met, thereby maximizing the heat dissipation effect, so that the airflow can flow more smoothly, thereby reducing energy consumption and pressure fluctuations of the airflow generator 130 and prolonging the service life of the airflow generator 130. Therefore, by forming the gas flow path as shown in FIG. 15, it is conducive to increasing the heat exchange area and also conducive to cooperating with the annular airflow formed above to jointly improve the heat dissipation effect and heat dissipation efficiency.

It is to be noted that only the main fluid path is illustrated in FIG. 15, which does not necessarily mean that other fluid paths do not exist. Certainly, in the embodiments of the present disclosure, the annular airflow formed between the first vent k1a and the second vent k1b is a main annular airflow path, and is also a main gas flow path between the first cavity Q1 and the second cavity Q2.

In some embodiments, still referring to FIG. 7, FIG. 10, and FIG. 13, the power conversion system 100 further includes a plurality of radiating fins 170. All the radiating fins 170 are located in the second cavity Q2 and are arranged on the partition wall 112. At least part of the radiating fins 170 are arranged in rows along the first direction F1 and are arranged in columns along a fourth direction. The first direction F1, the fourth direction, and the direction in which the first cavity Q1 points to the second cavity Q2 intersect with each other. In the embodiments of the present disclosure, the fourth direction (not shown) and the second direction F2 are parallel to each other.

In this way, the heat dissipation effect can be further improved through the radiating fins 170 arranged in an array.

It is to be noted that, in some embodiments of the present disclosure, required heat dissipation effects can be achieved by adjusting positions of the radiating fins 170, distances between the radiating fins 170 in different rows, and distances between different columns. For example, referring to FIG. 7 and FIG. 13, the radiating fins 170 can be arranged downstream of the first gap g1 along the first direction F1, so that the gaps between the liquid cooling members 120 and the heat dissipation effect of the radiating fins 170 can be utilized to a greater extent.

In some embodiments, still referring to FIG. 7, FIG. 10, and FIG. 13, the liquid inlet j1 and the liquid outlet j2 of the liquid cooling member 120 are both arranged adjacent to one of the two first sides b1. In this way, it is conducive to more compact arrangement of a corresponding cooling apparatus.

In some embodiments, still referring to FIG. 2 to FIG. 4, the second cavity Q2 is located on a bottom side of the first cavity Q1, and the direction in which the first cavity Q1 points to the second cavity Q2 is a direction of gravity. That is, the third direction F3 and the direction of gravity are parallel to each other.

In this way, it is conducive to improving the heat dissipation effect of the components in the first cavity Q1 and also conducive to arrangement of other components in the system using the power conversion system 100. Compared with a situation that the second cavity Q2 is located on a top side of the first cavity Q1, an influence of the above condensation on electrical insulation properties of the first cavity Q1 can be reduced, and overall safety performance can be improved.

In some embodiments, still referring to FIG. 1, the power conversion system 100 may have at least one of a photovoltaic interface, a battery interface, a grid input interface, a DC output interface, and an AC output interface (not shown).

Solar panels or other renewable energy generation systems and the power conversion system 100 can be connected through the photovoltaic interface. A battery and the power conversion system 100 are connected through the battery interface. The battery may store electrical energy, so that the electrical energy of the battery can be converted and outputted through the power conversion system 100. The grid input interface may be connected to high-voltage power from a power grid, which is then outputted to a low-voltage power device or system after voltage reduction by the power conversion system 100. The AC output interface may be connected to a product that requires an AC such as a household appliance. The power conversion system 100 converts the AC to a DC and outputs the DC to the appliance. The DC output interface may be connected to a device that requires DC power such as a charging pile.

In this way, flexible setting can be made according to actual usage requirements, thereby improving adaptability of the power conversion system 100 and meet usage requirements in different scenarios, which is not specifically limited herein.

Based on the same inventive concept, embodiments of the present disclosure provide an energy storage system, including the power conversion system 100 in any one of the above embodiments.

In some embodiments, the energy storage system further includes a battery, and the power conversion system 100 is electrically connected to the battery. The power conversion system 100 may convert energy generated by solar power, wind power, or fuel cells into a DC, store the DC in the battery, and output the electrical energy in the battery when needed. The energy storage system can provide a user with reliable energy reserves, and provide the user with backup power in case of power failure or power shortage, which is convenient for the user to use.

The energy storage system also has the advantages of the above power conversion system 100. Details are not repeat herein.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the specification.

The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

What is claimed is:

1. A power conversion system, comprising:
a tank comprising a body and a partition wall arranged in the body, the partition wall dividing an interior of the body into a first cavity and a second cavity, the partition wall being provided with a plurality of vents, the plurality of vents being communicated between the first cavity and the second cavity;
a liquid cooling member located in the second cavity and at least attached to the partition wall; and
an airflow generator arranged in the first cavity, the airflow generator being configured to input gas located in the second cavity into the first cavity via at least one vent and output gas located in the first cavity into the second cavity via at least another vent.

2. The power conversion system according to claim 1, wherein the partition wall has two first sides oppositely arranged along a first direction, the first direction intersecting with a direction in which the first cavity points to the second cavity;
wherein all the vents are arranged adjacent to the two first sides, respectively, and all the vents are configured to cooperate with the airflow generator to form an annular airflow that circulates from the first cavity to the second cavity.

3. The power conversion system according to claim 2, wherein in all the vents, the vents for air inlet are defined as first vents, and the vents for air outlet are defined as second vents;
wherein the airflow generator comprises at least one first airflow generating unit, and inlets of the first airflow generating unit and the first vents are communicated in one-to-one correspondence.

4. The power conversion system according to claim 3, wherein a plurality of first vents and a plurality of first airflow generating units are provided, and all the first vents are arranged adjacent to one of the first sides, and the second vents are arranged adjacent to another of the first sides.

5. The power conversion system according to claim 4, wherein one second vent is provided, orthographic projections of all the first vents on a reference plane are located within a range of an orthographic projection of the second vent on the reference plane, and the reference plane is a plane perpendicular to a direction in which the first side points to the second side.

6. The power conversion system according to claim 4, wherein all the first vents are sequentially spaced apart along a preset direction; and the preset direction, the first direction, and the direction in which the first cavity points to the second cavity are perpendicular to each other.

7. The power conversion system according to claim 4, wherein outlets of the first airflow generating units are arranged towards the second vents, and the outlets of the first airflow generating units are oriented parallel to the first direction.

8. The power conversion system according to claim 4, wherein two first vents and two first airflow generating units are provided, one of the first vents is arranged adjacent to one end of one of the first sides, and another of the first vents is arranged adjacent to another end of the one of the first sides.

9. The power conversion system according to claim 3, wherein the partition wall further has two second sides oppositely arranged along a second direction; each of the first sides connects the two second sides, each of the first sides and the two second sides define two corner portions; the first direction, the second direction, and the direction in which the first cavity points to the second cavity are perpendicular to each other; a plurality of first vents, a plurality of second vents, and a plurality of first airflow generating units are provided; wherein at least one of the first airflow generating units is arranged at a first target corner portion, and rest of the first airflow generating units are located at a second target corner portion; the first target corner portion and the second target corner portion are two corner portions in all the corner portions that are not adjacent along a circumferential direction of the partition wall; wherein at least one of the second vents is located on an air outlet path of at least one of the first airflow generating units, and rest of the second vents are located on air outlet paths of rest of the first airflow generating units.

10. The power conversion system according to claim 3, wherein the first airflow generating unit comprises a plurality of first airflow generating members; in a same first airflow generating unit, all the first airflow generating members are arranged side by side or stacked in the direction in which the first cavity points to the second cavity, and air outlet directions of all the first airflow generating members are parallel to each other and in a same direction.

11. The power conversion system according to claim 3, wherein at least one second vent is provided, the airflow generator comprises at least one second airflow generating unit, and inlets of the second airflow generating units and the second vents are communicated in one-to-one correspondence.

12. The power conversion system according to claim 3, further comprising a flow guiding member located in the first cavity, wherein an inlet of the first airflow generating unit is in communication with the corresponding first vent via the flow guiding member.

13. The power conversion system according to claim 2, wherein the liquid cooling member comprises a plurality of liquid cooling units sequentially connected along a circulating direction of a medium; and all the liquid cooling units are sequentially arranged along the first direction.

14. The power conversion system according to claim 13, wherein the liquid cooling unit located most upstream along the first direction is defined as a first liquid cooling unit, and the first liquid cooling unit comprises a plurality of first liquid cooling portions arranged in series along the circulating direction of the medium.

15. The power conversion system according to claim 13, wherein the liquid cooling unit located most downstream along the first direction is defined as a second liquid cooling unit, and the second liquid cooling unit comprises a plurality of second liquid cooling portions arranged in series along the circulating direction of the medium.

16. The power conversion system according to claim 13, wherein at least one liquid cooling unit between the liquid cooling unit located most upstream and the liquid cooling unit located most downstream along the first direction is defined as a third liquid cooling unit, and the third liquid cooling unit comprises a plurality of third liquid cooling portions arranged side by side in a direction perpendicular to the first direction.

17. The power conversion system according to claim 13, wherein along the first direction, the liquid cooling unit between the liquid cooling unit located most upstream and the liquid cooling unit located most downstream defines at least one first gap in communication with the second cavity; the at least one first gap has a target gap, and the partition wall is provided with an opening in communication with the target gap in a region located in the target gap; the power conversion system further comprises a printed circuit board (PCB) arranged in the first cavity, and a plurality of electronic components arranged on the PCB; and a second gap in communication with the opening is defined between the PCB and the partition wall.

18. The power conversion system according to claim 13, further comprising a plurality of radiating fins; all the radiating fins are located in the second cavity and are arranged on the partition wall; at least part of the radiating fins are arranged in rows along the first direction and are arranged in columns along a fourth direction; and the first direction, the fourth direction, and the direction in which the first cavity points to the second cavity intersect with each other; and/or
a liquid inlet and a liquid outlet of the liquid cooling member are both arranged adjacent to one of the two first sides.

19. The power conversion system according to claim 1, wherein the second cavity is located on a bottom side of the first cavity, and the direction in which the first cavity points to the second cavity is a direction of gravity.

20. An energy storage system, comprising the power conversion system according to claim 1.
